(19) United States
(12) Patent Application Publication
(10) Pub. No.: US 2025/0234670 A1
(43) Pub. Date: Jul. 17, 2025

(54) OPTICAL INTERCONNECTS USING 3D STACKED OPTOELECTRONIC INTERFACES

(71) Applicants: Robert Kalman, Sunnyvale, CA (US); Sunghwin Min, Sunnyvale, CA (US); Bardia Pezeshki, Sunnyvale, CA (US); Ivan Huang, Sunnyvale, CA (US); Emad Afifi, Sunnyvale, CA (US); Alexander Tselikov, Sunnyvale, CA (US)

(72) Inventors: Robert Kalman, Sunnyvale, CA (US); Sunghwin Min, Sunnyvale, CA (US); Bardia Pezeshki, Sunnyvale, CA (US); Ivan Huang, Sunnyvale, CA (US); Emad Afifi, Sunnyvale, CA (US); Alexander Tselikov, Sunnyvale, CA (US)

(21) Appl. No.: 19/024,132

(22) Filed: Jan. 16, 2025

Related U.S. Application Data
(60) Provisional application No. 63/621,568, filed on Jan. 16, 2024.

(51) Int. Cl. H10F 55/25; H01L 25/16

(52) U.S. Cl. CPC H10F 55/25; H01L 25/167

(57) ABSTRACT

Optoelectronic subassemblies may be bonded to base integrated circuit chips (ICs). The optoelectronic subassemblies may be ICs themselves, with optical emitters and/or photodetectors bonded to those ICs. In some embodiments active sides of the OE ICs may be bonded to active sides of the base ICs. In some embodiments non-active sides of the OE ICs may be bonded to active sides of the base ICs. In some embodiments active sides of the OE ICs may be bonded to non-active sides of the base ICs. And in some embodiments non-active sides of the OE ICs may be bonded to non-active sides of the base ICs.

### CROSS-REFERENCE TO RELATED APPLICATIONS

This application claims the benefit of U.S. Provisional Patent Application No. 63/621,568, filed on Jan. 16, 2024, the disclosure of which is incorporated by reference herein.

### BACKGROUND OF THE INVENTION

The need for high-performance computing and networking is ubiquitous and ever-increasing. Prominent applications include data center servers, high-performance computing clusters, artificial neural networks, and network switches.

Processing capabilities of integrated circuits (ICs) have been advancing faster than their IO for decades. This has resulted in problems such as the “memory wall,” where the performance of processing systems is limited to far less than optimum due to memory IO limitations.

A single IC can only contain so much functionality based on transistor count and power constraints. Additionally, different functions (e.g. logic, DRAM, I/O) require different process sequences, and thus not all the desired functions can be combined on a single integrated circuit.

In fact, there are significant benefits to “de-integrating” SoCs into smaller “chiplets”, including: The process for each chiplet can be optimized to its function, e.g. logic, DRAM, high-speed I/O, etc.; Chiplets are well-suited for reuse in multiple designs; Chiplets are generally less expensive to design; and Chiplets generally have higher yield because they are smaller with fewer devices.

However, a major drawback to chiplets compared to SoCs is that chiplets require a higher density of inter-chip connections. Compared to the on-chip connections between functional blocks in SoCs, chip-to-chip connections are typically much less dense and require far more power (normalized as energy per bit).

State-of-the-art chip-to-chip interconnects utilize interposers and bridges, where the chips are flip-chip bonded to a substrate that contains the chip-to-chip electrical traces. While such interconnects provide far higher density and far lower power than interconnects of packaged chips via a printed circuit board (PCB), they still fall very far short of what is desired: chip-to-chip interconnects that approach the density and power dissipation of intra-chip interconnects.

The power and maximum reach of electrical interconnects are fundamentally limited by capacitance and conductor resistance. Interconnect density is limited by conductor width and layer count. The capacitance C of short electrical interconnects is proportional to interconnect length and approximately independent of conductor width w (assuming dielectric thickness scales approximately proportionately). The resistance R of electrical connections, and thus the maximum length (limited by RC) is inversely proportional to the conductor cross-sectional area, which scales as w². The density of electrical connections is inversely proportional to w. Thus, there are trade-offs in interconnect density, length, and power, and these trade-offs are fundamental, being based on dielectric permittivity and conductor (e.g. copper) resistance.

Thus, electrical interconnects have fundamental limitations that constrain system performance and limit what is achievable with so-called “more than Moore” 2.5D and 3D advanced packaging. Optical interconnects, and more specifically 3D optical interconnects, do not suffer from these limitations.

### BRIEF SUMMARY OF THE INVENTION

The drive power and density of optical interconnects are largely independent of the length of the connection. With regard to density, multi-layer planar optical interconnects can achieve densities that are on the same order of the density of electrical interconnects. However, “3D” optical interconnects that are normal to the chip surface, possibly can achieve extraordinary densities that are far beyond what is possible with planar interconnects; densities of >2500 interconnects per mm² at 4 Gbps data rates are readily achievable, providing a throughput density of >1 Pbps/cm².

Some embodiments provide optical interconnects based on an optoelectronic IC bonded to a base IC in a “3D” stack.

In some aspects, an end of an optical interconnect, comprises: a substrate; a base semiconductor chip having an active side bonded to the substrate and a non-active side facing away from the substrate; and an optoelectronic (OE) semiconductor chip having a non-active side bonded to the non-active side of the base semiconductor chip, the OE semiconductor chip having microLEDs and/or photodetectors bonded to an active side of the OE semiconductor chip, the OE semiconductor chip having Tx circuitry including microLED drivers and Rx circuitry including transimpedance amplifiers. In some such aspects, the base semiconductor chip includes physical media dependent (PMD) circuitry. In some such aspects the PMD circuitry includes encoders and scramblers. In some such aspects the OE semiconductor chip includes physical media dependent (PMD) circuitry. In some such aspects the PMD circuitry includes encoders and scramblers. In some such aspects the OE semiconductor chip includes through silicon vias (TSVs) between the non-active side and the active side of the OE semiconductor chip.

In some aspects, an end of an optical interconnect, comprises: a substrate; a base semiconductor chip having an active side bonded to the substrate and a non-active side facing away from the substrate; and an optoelectronic (OE) semiconductor chip having an active side bonded to the non-active side of the base semiconductor chip, the OE semiconductor chip having microLEDs and/or photodetectors bonded to a non-active side of the OE semiconductor chip, the OE semiconductor chip having Tx circuitry including microLED drivers and Rx circuitry including transimpedance amplifiers. In some such aspects the base semiconductor chip includes physical media dependent (PMD) circuitry. In some such aspects the PMD circuitry includes encoders and scramblers. In some such aspects the OE semiconductor chip includes physical media dependent (PMD) circuitry. In some such aspects the PMD circuitry includes encoders and scramblers. In some such aspects the OE semiconductor chip includes through silicon vias (TSVs) between the non-active side and the active side of the OE semiconductor chip.

These and other aspects of the invention are more fully comprehended upon review of this disclosure.

### BRIEF DESCRIPTION OF THE FIGURES

FIGS. 1a-d are block diagrams of embodiments of one end of an optical interconnect between ICs, in accordance with aspects of the invention.

FIGS. 2a-e are cross-sectional views of embodiments of optoelectronic subassemblies, in accordance with aspects of the invention.

FIGS. 3a-c show top and side views illustrating relative areas of embodiments of base ICs and optoelectronic ICs bonded together, in accordance with aspects of the invention.

FIGS. 4a-h are front-side cross-sectional views showing relative arrangements of base ICs, optoelectronic ICs, and substrates, in accordance with aspects of the invention.

FIGS. 5a-b are front-side cross-sectional views showing relative arrangements of base ICs, optoelectronic substrates, and molded wafers, in accordance with aspects of the invention.

### DETAILED DESCRIPTION

The inventions described herein relate to implementing optical interconnects between integrated circuits (ICs). Each end of the interconnect comprises a base IC to which one or more optoelectronic (OE) subassemblies are electrically bonded in a “3D” stack. An OE subassembly (SA) comprises at least electrical-to-optical (E2O) conversion and/or optical-to-electrical (O2E) conversion functionality. In some embodiments, the base ICs comprise processing, switching, and/or memory functionality.

Some embodiments of an OE SA comprise one or more optical emitters mounted to a passive substrate or an IC. In some embodiments, the emitters comprise one or more microLEDs. Some embodiments of an OE SA comprise one or more photodetectors (PDs) mounted to a passive substrate or an IC. In some embodiments, the emitters and/or PDs are located on a regular grid, for instance a hexagonal close-packed (HCP), square, or rectangular grid. In some embodiments, the center-to-center spacing of grid elements may be in the range of 10 um-100 um.

In some embodiments comprising microLED emitters, a microLED is made from a p-n junction of a direct-bandgap semiconductor material. In some embodiments a microLED is distinguished from a semiconductor laser (SL) as follows: (1) a microLED does not have an optical resonator structure; (2) the optical output from a microLED is almost completely spontaneous emission, whereas the output from a SL is dominantly stimulated emission; (3) the optical output from a 15 microLED is temporally and spatially incoherent, whereas the output from a SL has significant temporal and spatial coherence; (4) a microLED is designed to be driven down to a zero minimum current, whereas a SL is designed to be driven down to a minimum threshold current, which is typically at least 1mA. In some embodiments a microLED is distinguished from a standard LED by (1) having an emitting region of less than 10 μm×10 μm; (2) frequently having cathode and anode contacts on top and bottom surfaces, whereas a standard LED typically has both positive and negative contacts on a single surface; (3) typically being used in large arrays for display and interconnect applications. In some embodiments, each microLED is made from the GaN material system with InGaN quantum wells. In some embodiments, each microLED is made from the GaAs or InP material system.

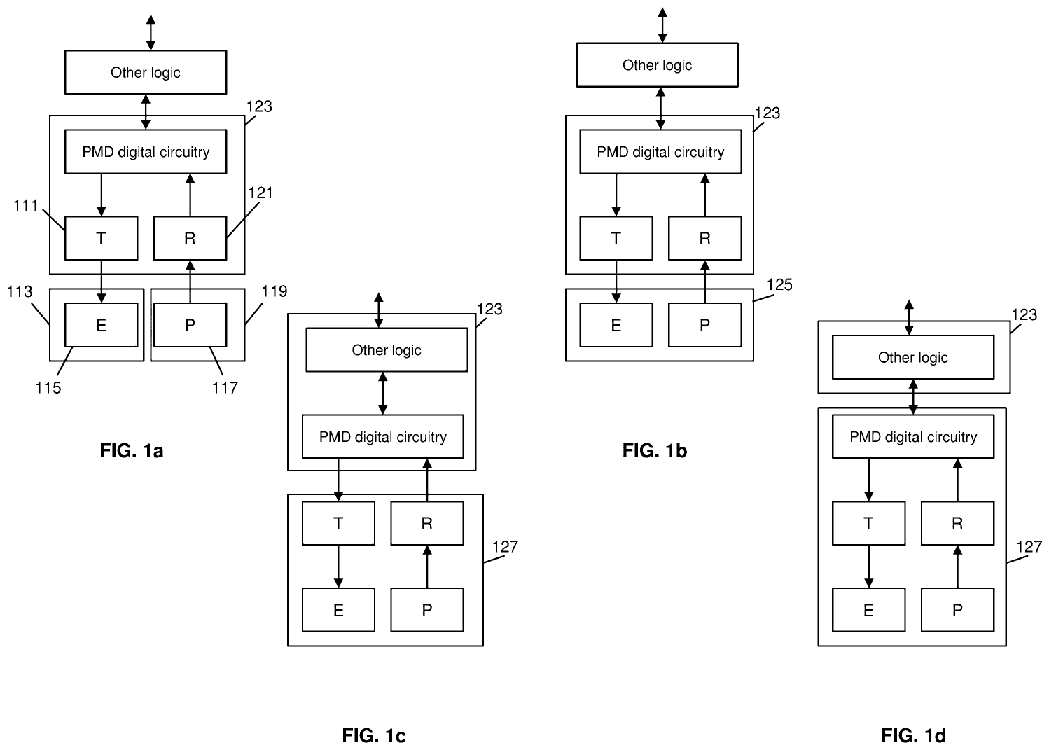

FIGS. 1a-d show block diagrams of various embodiments of one end of an optical interconnect between ICs. The one end of the optical interconnect generally comprises a base IC and one or more passive substrates or ICs, together comprising OE components, transmitter (Tx) and receiver (Rx) circuitry, and other logic.

In some embodiments, the Tx circuitry 111 comprises emitter drivers, each of which takes a logic level input and outputs an analog signal appropriate for driving the emitter, e.g. a current drive with a DC bias term and a modulation term that varies in response to the digital input. In some embodiments, this drive signal may support emphasis of some frequency components relative to others in the driver output, e.g., emphasis of the high-frequency components relative to the low-frequency components. In some embodiments, these transmitter circuits comprise additional digital functionality allowing, for instance, control of the voltage, current, and frequency emphasis levels of the signals driving the emitters, and monitoring of the drive signals and/or the light output of each emitter. In some embodiments, the Tx circuits may include other physical media-dependent (PMD) circuitry such as encoders and/or scramblers.

In some embodiments, the Rx circuitry 121 comprises transimpedance amplifiers (TIAs), each of which takes a photocurrent and amplifies it to a voltage swing, where the gain of the TIA is characterized by a transimpedance gain. In some embodiments, the Rx circuits comprise additional limiting amplifier (LA) stages that amplify the signal to a logic level output. In some embodiments, Rx electronics may support emphasis of some frequency components relative to others, e.g. emphasis of the high-frequency components relative to the low-frequency components. Examples of such a structure includes a decision feedback equalizer (DFE) and a continuous time linear equalizer (CTLE). In some embodiments, these Rx circuits comprise additional digital functionality allowing, for instance, control of the TIA gain, frequency characteristics of the equalizers, and monitoring of the received optical power levels. In some embodiments, the Rx circuits may include other physical media-dependent (PMD) circuitry such as clock recovery circuits, decoders and/or descramblers.

The system may be partitioned such that the functionality is distributed between the different ICs and subassemblies in different ways. In some embodiments, for example as illustrated in FIG. 1a, Tx circuitry and Rx circuitry are part of a base chip 123, separate from OE subassemblies. The Tx circuitry receives signals for transmission from PMD circuitry, also on the base chip, and the Rx circuitry provides received signals to the PMD circuitry. The PMD circuitry may be in communication with other logic circuitry, located off the base chip.

An emitter SA receives signals for driving optical emitters from the Tx circuitry. The emitter SA comprises a separate IC or passive substrate 113 and one or more optical emitters 115. A PD SA provides received signals to the Rx circuitry. The PD SA also comprises a separate IC or passive substrate 119 and one or more PDs 117 or avalanche photodiodes (APDs).

In some embodiments of an OE SA, both the optical emitters and PDs are located on a common OE passive substrate or IC, for example as shown in FIG. 1b. In FIG. 1b, as with the embodiment of FIG. 1a, the Tx and Rx circuitry are located on the base IC, separate from the OE SA.

In some embodiments of an OE SA, for example as shown in FIG. 1c, some part, or all, of the Tx circuitry, for instance the emitter drive circuits, are located on an OE IC 127, while some other Tx circuitry may be located on the base IC. In some embodiments, some part, or all, of the Rx circuitry, for instance the TIAs and LAs, are located on the OE IC, while some other Rx circuitry is located on the base IC. In FIG. 1c, the PMD circuitry is shown as being in the base chip 123, as is the other logic. In some embodiments, however, the OE IC may also include more Tx and Rx circuitry, for instance the PMD circuitry enumerated previously, for example as shown in FIG. 1d. In such embodiments the other logic circuitry may be part of the base chip 123. The OE SA may be implemented in numerous ways, some of which are enumerated in

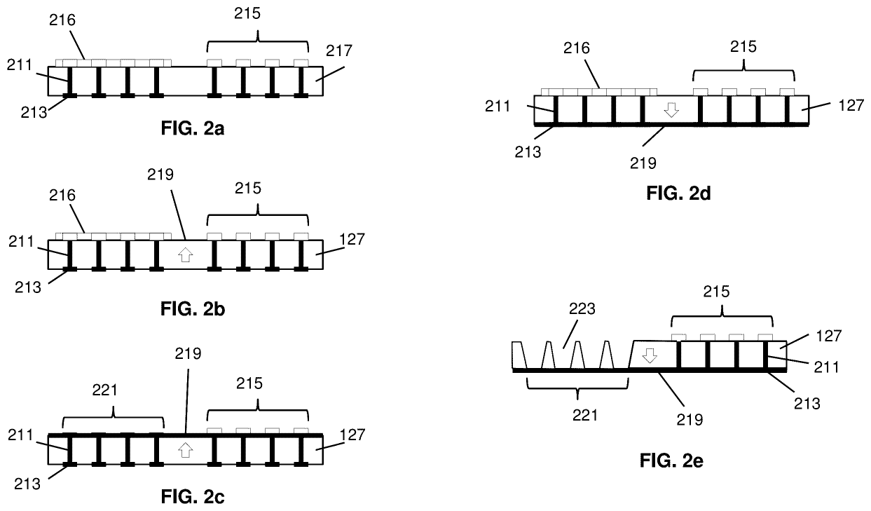

FIGS. 2a-e. In some embodiments, for example as shown in FIG. 2a, the OE SA comprises a passive substrate 217 that does not contain active electrical circuits. Such a substrate may be made from silicon, multi-layer ceramic, multi-layer organic, or other materials. In some embodiments, an array of emitters 215 (for instance, microLEDs) and/or PDs 216 may be attached to one surface of the substrate. Such a substrate typically comprises through-substrate vias 211 or through-silicon vias (TSVs) to provide electrical connectivity between the one surface of the substrate and an opposing surface, which includes electrical pads 213.

In some embodiments, for example as shown in FIGS. 2b-e, the OE SA comprises an IC 127, with TSVs 211 connecting between the two surfaces (or “sides”) of the substrate. In the figures, the arrow in the IC points toward the “active” IC side containing the active circuitry 219. The active circuitry may occupy any subset of the IC area. In some embodiments, for example as shown in FIG. 2b, an array of PDs 216 (or APDs) and an array of emitters 215 is bonded to the active side of the IC. In some embodiments, for example as shown in FIG. 2c, an array of PDs/APDs 221 is monolithically integrated with the IC electronics. For the embodiments shown in FIG. 2a-c, bonding pads 213 on the non-active side of the substrate enable the OE IC to be bonded to a base IC.

In some embodiments, for example as shown in FIGS. 2d, an array of emitters 215 and an array of PDs/APDs 216 is bonded to the non-active side of an IC, and is connected to the active surface of the IC by TSVs. In some embodiments, for example as shown in FIG. 2e, an array of emitters 215 is bonded to the non-active side of a OE IC while apertures 223 are etched through the IC on the PD part of the IC to allow “backside” illumination of PDs 221 integrated into the active circuitry side of the IC.

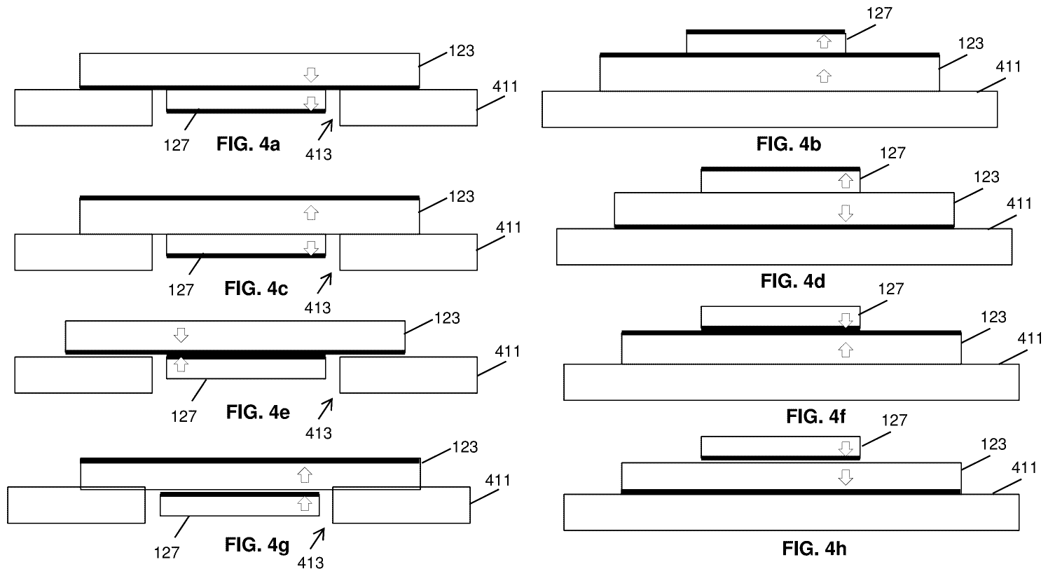

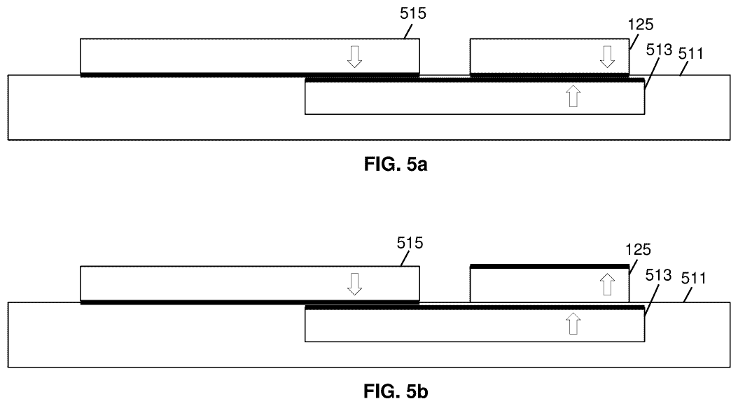

The various OE SA embodiments of FIGS. 2a-e can be bonded to a base IC in a variety of ways to create a “3D” stack, some embodiments of which are shown in FIGS. 4a-h and FIGS. 5a-b. In those figures, arrows in the ICs point toward the “active” side of that IC that contains active circuitry such as transistors. The bonds between the base IC and OE IC may comprise C4 solder bumps, microbumps, or direct bond interconnects (DBI).

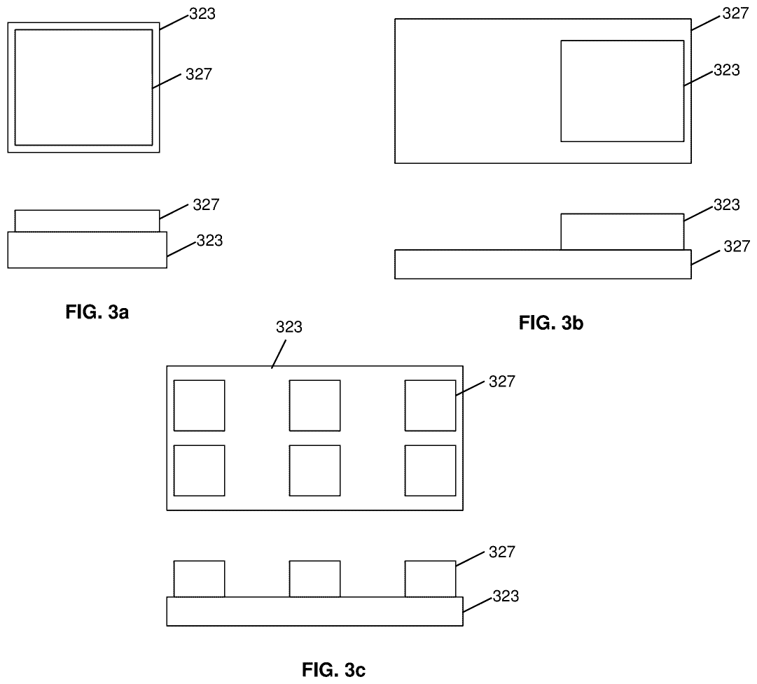

FIGS. 3a-c show top and side views illustrating relative areas of embodiments of base ICs (or passive substrates) and optoelectronic ICs bonded together. In some embodiments, the OE IC or passive substrate 327 has approximately the same footprint as the base IC 323, for example as shown in FIG. 3a. In some embodiments, the OE IC or passive substrate 327 has a larger footprint than the base IC 323, for example as shown in FIG. 3b. In some embodiments, the OE IC has a smaller footprint than the base IC. In some embodiments, each OE IC has a significantly smaller footprint than the base IC 323, and multiple OE ICs 327 are bonded to the base IC, for example as shown in FIG. 3c.

In some embodiments, one or more OE ICs have emitters and/or PDs bonded to their active side, for example as discussed with respect to FIGS. 2a-c. In some such embodiments, those ICs have their non-active side bonded to an active side of a base IC. For example, FIG. 4a shows a base IC 123 having an active side attached to a substrate 411. The substrate may be a package substrate or an interposer, for example. The substrate includes an aperture 413. An OE IC 127 is within the aperture with a non-active side of the OE IC bonded to the active side of the base IC. The active side of the OE IC faces away from the base IC, with a result that light can travel in or through the aperture towards and away from the active side of the OE IC, allowing an optical coupling to any emitters and/or PDs on that active side. For convenience of viewing, arrows are placed within the base IC and OE IC for all of FIGS. 4a-h, with the arrows pointing towards the active side of the ICs in which the arrows are located. In some alternative embodiments, for example as shown in FIG. 4b, the non-active side of the base IC 123 may be bonded to a package substrate or interposer 411, with TSVs to connect the non-active side to the active side. The OE IC 127 is bonded, on its non-active side, to the active side of the base IC.

In some embodiments, the non-active side of one or more OE ICs may be bonded to the non-active side of a base IC. In some such embodiments the OE ICs and the base IC includes TSVs to connect between their two surfaces. Each OE IC comprises emitters and PDs on its active side. In some such embodiments, for example as shown in FIG. 4c, the non-active side of the base IC 123 may be bonded to a package substrate or interposer 411. The package substrate or interposer has one or more apertures 413 to allow optical coupling to the emitters and PDs on the OE IC 127. The base IC is bonded to the package substrate or interposer about the aperture, and the OE IC is largely within the aperture and has its non-active side bonded to the base IC. In some alternative embodiments, the active side of the base IC 123 may be bonded to a package substrate or interposer 411, for example as shown in FIG. 4d, with TSVs coupling the active side and the non-active side of the base IC. The OE IC 123 may have its non-active side bonded to the non-active side of the base IC, with an active side of the OE IC facing away from the base IC. Again, TSVs may electrically couple the non-active and active sides of the OE IC.

In some embodiments, the active side of one or more OE ICs is bonded to the active side of a base IC. In such embodiments, the emitters and/or PDs may be bonded to the non-active side of each OE IC. In some such embodiments, for example as shown in FIG. 4e, the active side of the base IC 123 may be bonded to a package substrate or interposer 411. The package substrate or interposer may have one or more apertures 413 to allow optical coupling to the emitters and PDs on each OE IC, and the base IC may be bonded to the package substrate or interposer over the apertures. The OE IC 127 may be largely within the aperture, with an active side of the OE IC bonded to the active side of the base IC. In some alternative embodiments, for example as shown in FIG. 4f, the non-active side of the base IC 123 may be bonded to a package substrate or interposer 411. The base IC may include TSVs to connect the non-active side to the active side. The active side of the OE IC 127 may be bonded to the active side of the base IC.

In some embodiments, the active side of one or more OE ICs is bonded to the non-active side of a base IC. Emitters and/or PDs may be bonded to the non-active side of the OE ICs. The base IC may include TSVs to connect between non-active and active sides of the base IC. In some such embodiments, the non-active active side of the base IC 123 may be bonded to a package substrate or interposer 411 about one or more apertures 413 of the package substrate or interposer, for example as shown in FIG. 4g. The apertures of the package substrate or interposer allow optical coupling to the emitters and/or PDs on the OE IC, which is largely within the aperture. The OE IC has its active side bonded to the non-active side of the base IC. In some alternative embodiments, the active side of the base IC 123 may be bonded to a package substrate or interposer, with the active side of the OE IC bonded to the non-active side of the base IC.

FIGS. 5a-b are front-side cross-sectional views showing relative arrangements of base ICs, optoelectronic substrates, and molded wafers. FIG. 5a shows a first IC (IC1) 513 embedded in a molded wafer 511. An active side of IC1, about the level of a side of the molded wafer, is bonded to an active side of one or more OE ICs 125. As with other figures, arrows are placed within the ICs for convenience of viewing, with the arrows pointing towards the active side of the ICs in which the arrows are located. Optical emitters and/or PDs are bonded to the non-active side of the OE IC, for example as discussed with respect to FIG. 2a, d, or e. In some embodiments, the wafer may be molded from a polymer.

In some alternative embodiments, the non-active side of an OE IC 125 is bonded to the active side of a first IC (IC1) 513 embedded in a molded wafer 511, for example as shown in FIG. 5b. Optical emitters and/or PDs may be on the active side of the OE IC, for example as discussed with respect to FIG. 2b or c.

A second IC (IC2) 515 may also be bonded to IC1, as shown in both FIGS. 5a and 5b. As illustrated, an active side of IC2 is bonded to a portion of the active side of IC1.

Although the invention has been discussed with respect to various embodiments, it should be recognized that the invention comprises the novel and non-obvious claims supported by this disclosure.

What is claimed is:

1. An end of an optical interconnect, comprising:
a substrate;
a base semiconductor chip having an active side bonded to the substrate and a non-active side facing away from the substrate; and
an optoelectronic (OE) semiconductor chip having a non-active side bonded to the non-active side of the base semiconductor chip, the OE semiconductor chip having microLEDs and/or photodetectors bonded to an active side of the OE semiconductor chip, the OE semiconductor chip having Tx circuitry including microLED drivers and Rx circuitry including transimpedance amplifiers.

2. The end of the optical interconnect of claim 1, wherein the base semiconductor chip includes physical media dependent (PMD) circuitry.

3. The end of the optical interconnect of claim 2, wherein the PMD circuitry includes encoders and scramblers.

4. The end of the optical interconnect of claim 1, wherein the OE semiconductor chip includes physical media dependent (PMD) circuitry.

5. The end of the optical interconnect of claim 4, wherein the PMD circuitry includes encoders and scramblers.

6. The end of the optical interconnect of claim 1, wherein the OE semiconductor chip includes through silicon vias (TSVs) between the non-active side and the active side of the OE semiconductor chip.

7. An end of an optical interconnect, comprising:
a substrate;
a base semiconductor chip having an active side bonded to the substrate and a non-active side facing away from the substrate; and
an optoelectronic (OE) semiconductor chip having an active side bonded to the non-active side of the base semiconductor chip, the OE semiconductor chip having microLEDs and/or photodetectors bonded to a non-active side of the OE semiconductor chip, the OE semiconductor chip having Tx circuitry including microLED drivers and Rx circuitry including transimpedance amplifiers.

8. The end of the optical interconnect of claim 7, wherein the base semiconductor chip includes physical media dependent (PMD) circuitry.

9. The end of the optical interconnect of claim 8, wherein the PMD circuitry includes encoders and scramblers.

10. The end of the optical interconnect of claim 1, wherein the OE semiconductor chip includes physical media dependent (PMD) circuitry.

11. The end of the optical interconnect of claim 10, wherein the PMD circuitry includes encoders and scramblers.

12. The end of the optical interconnect of claim 7, wherein the OE semiconductor chip includes through silicon vias (TSVs) between the non-active side and the active side of the OE semiconductor chip.
